(19) United States
(12) Patent Application Publication
(10) Pub. No.: US 2026/0353828 A1
(43) Pub. Date: Nov. 5, 2026

(54) INTEGRATED CIRCUIT WITH AND METHOD FOR CONNECTION OF A PLURALITY OF FLOATING DIFFUSION REGIONS

(71) Applicant: Taiwan Semiconductor Manufacturing Company, Ltd., Hsinchu (TW)

(72) Inventors: Po-Wei Fong, New Taipei City (TW); Chen-Jong Wang, Hsin-Chu (TW); Dun-Nian Yaung, Taipei City (TW); Chao-Te Liu, Kaohsiung City (TW); Szu-Ying Chen, Miaoli County (TW)

(21) Appl. No.: 19/738,701

(22) Filed: Jul. 13, 2026

Related U.S. Application Data
(62) Division of application No. 18/164,014, filed on Feb. 3, 2023.

(51) Int. Cl. H10F 39/00

(52) U.S. Cl. CPC H10F 39/8037; H10F 39/011; H10F 39/807; H10F 39/811

(57) ABSTRACT

Some embodiments relate to an integrated circuit including a semiconductor substrate having a first semiconductor substrate region and a second semiconductor substrate region. A first floating diffusion region is situated within the first semiconductor substrate region and a second floating diffusion region is situated within the second semiconductor substrate region. An isolation region is disposed between the first semiconductor substrate region and the second semiconductor substrate region. A gate structure is disposed over the semiconductor substrate abutting the first semiconductor substrate region. A conductive layer is directly connected to the first floating diffusion region and to the second floating diffusion region. The gate structure has a greater maximum height than the conductive layer.

### REFERENCE TO RELATED APPLICATION

This Application is a Divisional of U.S. application Ser. No. 18/164,014, filed on Feb. 3, 2023, the contents of which are hereby incorporated by reference in their entirety.

### BACKGROUND

Integrated circuits (IC) with image sensors are used in a wide range of modern day electronic devices, such as cameras and cell phones, for example. In recent years, complementary metal-oxide semiconductor (CMOS) image sensors have begun to see widespread use, largely replacing charge-coupled devices (CCD) image sensors. Compared to CCD image sensors, CMOS image sensors are increasingly favored due to low power consumption, a small size, fast data processing, a direct output of data, and low manufacturing cost. Some types of CMOS image sensors include front-side illuminated (FSI) image sensors and back-side illuminated (BSI) image sensors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional elevation view diagram illustrating some embodiments of a portion of a pixel circuit array of an image sensor.

FIG. 2 is a cross-sectional plan view diagram illustrating some embodiments of a portion of a pixel circuit array of an image sensor.

FIG. 3 is a cross-sectional elevation view diagram illustrating some embodiments of a larger portion of a pixel circuit array of an image sensor.

FIG. 4 is a cross-sectional plan view diagram illustrating some embodiments of a portion of a pixel circuit array of an image sensor showing a conductive layer connecting a plurality of floating diffusions to a common contact.

FIG. 5 is a top view diagram illustrating some embodiments of a portion of a pixel circuit array of an image sensor showing a conductive layer connecting a plurality of floating diffusions to a common contact.

FIG. 6 is a top view diagram illustrating some embodiments of a portion of a pixel circuit array of an image sensor showing a conductive layer connecting a plurality of floating diffusions to a common contact.

FIG. 7 is a top view diagram illustrating some embodiments of a portion of a pixel circuit array of an image sensor showing a conductive layer connecting a plurality of floating diffusions to a common contact.

FIG. 8 is a cross-sectional plan view diagram illustrating some embodiments of a portion of a pixel circuit array of an image sensor.

FIGS. 9 through 25 are cross-sectional elevation view diagrams illustrating some embodiments of a series of incremental manufacturing steps as a series of cross-sectional views.

FIG. 26 is a flow diagram illustrating some embodiments of a methodology in flowchart format in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Electronic image sensors are used in a variety of devices to provide camera and other imaging functionality for visible light and across other portions of the electromagnetic spectrum (e.g., near infrared light). As image sensors are called upon to provide higher resolution imaging, faster imaging, and lower power consumption, there is a desire for new technology to provide improved image sensor performance.

When a semiconductor assembly (e.g., an integrated chip) is produced by forming different structures upon which semiconductor devices have been fabricated, accurate positioning of the structures can be challenging to achieve. Challenges faced increase with photodiode pitch shrinkage, as features to be positioned in relation to one another are smaller. For example, smaller pixel circuits can increase the difficulty of accurate overlay control to provide contact landings on each floating diffusion. Moreover, closely spaced contacts for each floating diffusion result in an array of metallic contact structures in close proximity to one another disposed in a dielectric material, which increases unwanted parasitic capacitance between adjacent floating diffusions. A new solution is desired to reduce such challenges and problems and to provide better manufacturability and improved performance of image sensors.

In accordance with at least one embodiment, a common connection is provided to multiple floating diffusion regions of an integrated circuit. Such a common connection can be provided by a direct electrical connection (e.g., ohmic coupling) between a conductive layer (e.g., conductive interconnect layer M0) and a plurality of floating diffusion regions (e.g., n-type semiconductor regions) without an intervening elongated electrical conductor (e.g., a via or contact) passing through a dielectric material in proximity to other elongated electrical conductors. Accordingly, parasitic capacitance that would otherwise exist between elongated electrical conductors, typically oriented in parallel and separated by a dielectric material, can be mitigated. Reduction of parasitic capacitance can enable higher performance of an image sensor even at higher pixel densities.

In some embodiments, the conductive layer can provide a common electrical interconnection of a plurality of floating diffusion regions of a plurality of photodiodes of an image sensor. A contact can be formed to directly connect to the conductive layer (e.g., via ohmic coupling), obviating the need for a plurality of individual contacts for the plurality of floating diffusion regions. For example, if each pixel circuit had its own contact extending through an interlayer dielectric, parasitic capacitance would exist with contacts for adjacent floating diffusion regions, and more such parasitic capacitance would be more severe with pixel pitch shrinkage to increase pixel density and image sensor resolution. When pixel design rules scale down, using the conductive layer to contact multiple floating diffusion regions reduces parasitic capacitance.

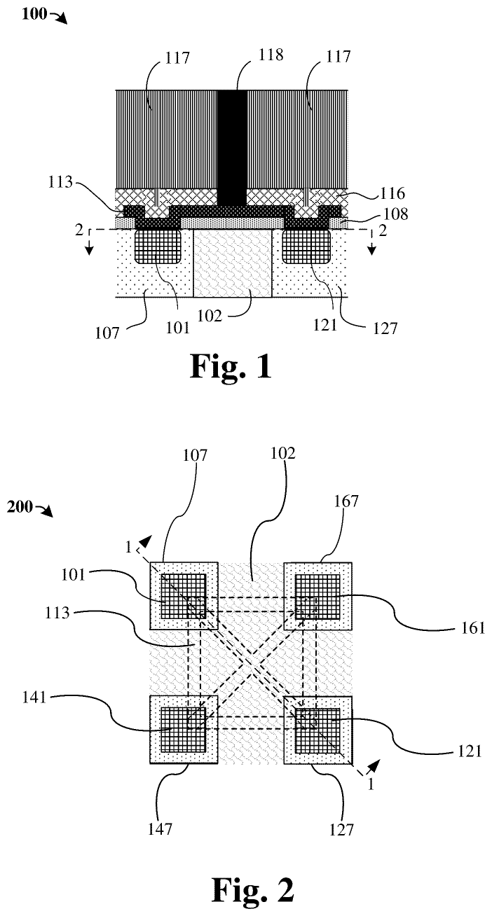

FIG. 1 is a cross-sectional elevation view diagram illustrating some embodiments of a portion 100 of a pixel circuit array of an image sensor. A dashed line extending diagonally through FIG. 2 shows the cross section illustrated in FIG. 1. An isolation region 102 is formed in a semiconductor substrate to isolate semiconductor substrate region 107 for a first pixel from semiconductor substrate region 127 for a second pixel. As an example, isolation region 102 may be an oxide dielectric region, a shallow trench isolation region, a deep trench isolation region, or the like. A floating diffusion region 101 is formed within semiconductor substrate region 107. Floating diffusion region 101 extends into semiconductor substrate region 107 from a first surface of semiconductor substrate region 107. A floating diffusion region 121 is formed within semiconductor substrate region 127. Floating diffusion region 121 extends into semiconductor substrate region 127 from a first surface of semiconductor substrate region 127. In some embodiments, the first semiconductor substrate region 107 and semiconductor substrate region 127 are p-type regions (e.g., regions doped with p-type dopants). In some embodiments, the floating diffusion region 101 is an n-type regions (e.g., a region doped with n-type dopants).

A dielectric layer 108 abuts the first surface of semiconductor substrate region 107 and the first surface of semiconductor substrate region 127. Apertures are provided in dielectric layer 108 at the locations of floating diffusion regions 101 and 121. A conductive layer 113 is disposed over a first portion of dielectric layer 108, over floating diffusion region 101, and over floating diffusion region 121, electrically connecting a first surface of floating diffusion region 101 to a first surface of floating diffusion region 121. Contact etch stop layer 116 is disposed directly over and in contact with conductive layer 113 and directly over and in contact with portions of dielectric layer 108 not covered by conductive layer 113. Interlayer dielectric region 117 is disposed over and in contact with contact etch stop layer 116.

An opening is formed through interlayer dielectric region 117 and contact etch stop layer 116, with the opening extending to a portion of a first surface of conductive layer 113. A contact 118 of electrically conductive material (e.g., metal) is formed within the opening, providing an electrical connection from the portion of the first surface of conductive layer 113 that extends from the first surface of conductive layer 113 to a first surface of interlayer dielectric region 117 opposite a second surface of interlayer dielectric region 117 in contact with contact etch stop layer 116.

FIG. 2 is a cross-sectional plan view diagram illustrating some embodiments of a portion 200 of a pixel circuit array of an image sensor. A dashed line extending across FIG. 1 shows the cross section illustrated in FIG. 2. In addition to the elements shown in FIG. 1 and transected by the dashed line in FIG. 2, other elements in FIG. 2 lie outside the plane of the illustration of FIG. 1.

Floating diffusion region 141 is shown formed within semiconductor substrate region 147. Floating diffusion region 161 is shown formed within semiconductor substrate region 167. Semiconductor substrate region 107, semiconductor substrate region 127, semiconductor substrate region 147, and semiconductor substrate region 167 are isolated from one another by isolation region 102. Floating diffusion region 101 within semiconductor substrate region 107, floating diffusion region 121 within semiconductor substrate region 127, floating diffusion region 141 within semiconductor substrate region 147, and floating diffusion region 161 within semiconductor substrate region 167 illustrate a portion 200 of a pixel element array of an image sensor. The pixel element array may extend to include many pixels beyond those illustrated in FIG. 2.

A variety of examples of patterns of a conductive layer 113 to electrically connect floating diffusion region 101, floating diffusion region 121, floating diffusion region 141, and floating diffusion region 161 together, to allow use of a common electrical contact, are shown in dashed line segments. As an example, a portion of conductive layer 113 can lie between and connect floating diffusion region 101 to floating diffusion region 161. As another example, a portion of conductive layer 113 can lie between and connect floating diffusion region 161 to floating diffusion region 121. As a further example, a portion of conductive layer 113 can lie between and connect floating diffusion region 121 to floating diffusion region 141. As yet another example, a portion of conductive layer 113 can lie between and connect floating diffusion region 141 to floating diffusion region 101. As still another example, a portion of conductive layer 113 can lie between and connect floating diffusion region 101 to floating diffusion region 121. As another example, a portion of conductive layer 113 can lie between and connect floating diffusion region 141 to floating diffusion region 161. Combinations of a plurality of such examples can connect more than two (e.g., three, four, or more) floating diffusion regions together to share a common contact. The connections provided by a pattern of conductive layer 113 are not limited to thin rectangular regions between pairs of floating diffusion regions but can include any suitable geometric shape or shapes, such as a polygon overlying all of the plurality of floating diffusion regions to be connected, a polygon with an portion or portions of the polygon removed to form an aperture or apertures, curved features (e.g., arcuate features), straight-line features, and so on, and combinations thereof.

In various embodiments, the conductive layer 113 may be formed from a conductive material, for example, a metal, a metal compound (such as a metal nitride), or the like. As examples, the conductive layer may comprise titanium nitride (TiN), titanium and titanium nitride (Ti/TiN), tantalum nitride (TaN), titanium (Ti), tantalum (Ta), copper (Cu), aluminum (Al), one or more other suitable conductive materials, or combinations thereof. Formation and patterning of the conductive layer 113, its interconnection with the plurality of floating diffusion regions, and the formation of and interconnection with a common contact can be achieved without complication of complementary metal oxide semiconductor (CMOS) fabrication processes.

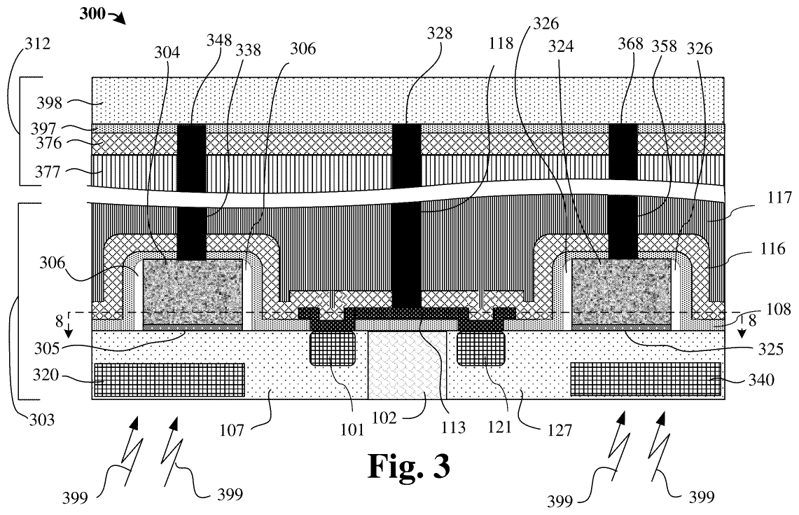

FIG. 3 is a cross-sectional elevation view diagram illustrating some embodiments of a larger portion 300 of a pixel circuit array of an image sensor. The pixel circuit array comprises the elements illustrated and recited with respect to FIG. 1 and additional elements beyond those of FIG. 1.

A transistor gate dielectric layer 305 is formed on a portion of the first surface of semiconductor substrate region 107. A transistor gate 304 is formed on a first surface of transistor gate dielectric layer 305, opposite a second surface of transistor gate dielectric layer 305 which is in contact with the first surface of semiconductor substrate region 107. Sidewall spacer 306 is formed along a side or sides of transistor gate 304. Dielectric layer 108 is formed over a first surface of transistor gate 304, opposite a second surface of transistor gate 304 in contact with transistor gate dielectric layer 305, and over a first end of sidewall spacer 306, opposite a second end of sidewall spacer 306 in contact with the first surface of semiconductor substrate region 107. Contact etch stop layer 116 is formed over dielectric layer 108. Interlayer dielectric region 117 is formed over contact etch stop layer 116. An opening is formed through interlayer dielectric region 117 and contact etch stop layer 116, with the opening extending to the first surface of transistor gate 304. A contact 338 of electrically conductive material (e.g., metal) is formed within the opening, providing an electrically connection from a portion of the first surface of transistor gate 304 to the first surface of interlayer dielectric region 117.

A transistor gate dielectric layer 325 is formed on a portion of the first surface of semiconductor substrate region 127. A transistor gate 324 is formed on a first surface of transistor gate dielectric layer 325, opposite a second surface of transistor gate dielectric layer 325 which is in contact with the first surface of semiconductor substrate region 127. Sidewall spacer 326 is formed along a side or sides of transistor gate 324. Dielectric layer 108 is formed over a first surface of transistor gate 324, opposite a second surface of transistor gate 324 in contact with transistor gate dielectric layer 325, and over a first end of sidewall spacer 326, opposite a second end of sidewall spacer 326 in contact with the first surface of semiconductor substrate region 127. As described above, contact etch stop layer 116 is formed over dielectric layer 108, and interlayer dielectric region 117 is formed over contact etch stop layer 116. An opening is formed through interlayer dielectric region 117 and contact etch stop layer 116, with the opening extending to the first surface of transistor gate 324. A contact 358 of electrically conductive material (e.g., metal) is formed within the opening, providing an electrically connection from a portion of the first surface of transistor gate 324 to the first surface of interlayer dielectric region 117.

Semiconductor region 320 is formed in semiconductor substrate region 107. Semiconductor region 320 has a first doping type (e.g., p-type) that is different than a second doping type (e.g., n-type) of semiconductor substrate region 107 so as to form a photodiode for a first pixel of a pixel array, the photodiode sensitive to incident electromagnetic radiation (e.g., light) 399. semiconductor region 340 is formed in semiconductor substrate region 127. Semiconductor region 340 has the first doping type and semiconductor substrate region 107 has the second doping type so as to form a photodiode for a second pixel of the pixel array, the photodiode sensitive to incident electromagnetic radiation (e.g., light) 399. Together, the aforementioned elements constitute an integrated circuit 303.

Second integrated circuit 312 comprises semiconductor substrate 398, dielectric layer 397, contact etch stop layer 376, interlayer dielectric 377, contact 328, contact 348, and contact 368. Features (not shown) such as transistors and other components may be formed in or on semiconductor substrate 398. Dielectric layer 397 is formed on a first surface of semiconductor substrate 398 and may extend over components. Contact etch stop layer 376 is formed on a first surface of dielectric layer 397. Interlayer dielectric 377 is formed on a first surface of contact etch stop layer 376. Apertures are formed through the interlayer dielectric 377, the contact etch stop layer 376, and dielectric layer 397. An electrically conductive material, such as metal, is disposed within the apertures to form contact 328, contact 348, and contact 368,

Second integrated circuit 312 is mated to integrated circuit 303 to form a stacked integrated circuit structure. In some embodiments, the stacked integrated circuit structure is a back-illuminated image sensor, also referred to as a backside-illumination (BSI) image sensor, which can detect electromagnetic energy (e.g., light) 399 incident upon integrated circuit 303 while providing electrical connections to second integrated circuit 312. In some embodiments, BSI images sensors may comprise photodiodes formed in integrated circuit 303, and the second side of integrated circuit 303 can be thinned to allow the incident electromagnetic energy to reach the photodiodes without excessive attenuation and without being blocked by structures fabricated on the first side of integrated circuit 303. However, a process window of contact would be critical in complicated layout environment, as the tolerances for fabrication of contacts on integrated circuit 303 and second integrated circuit 312 and the tolerances for alignment of the mating of integrated circuit 303 and second integrated circuit 312 would be tight.

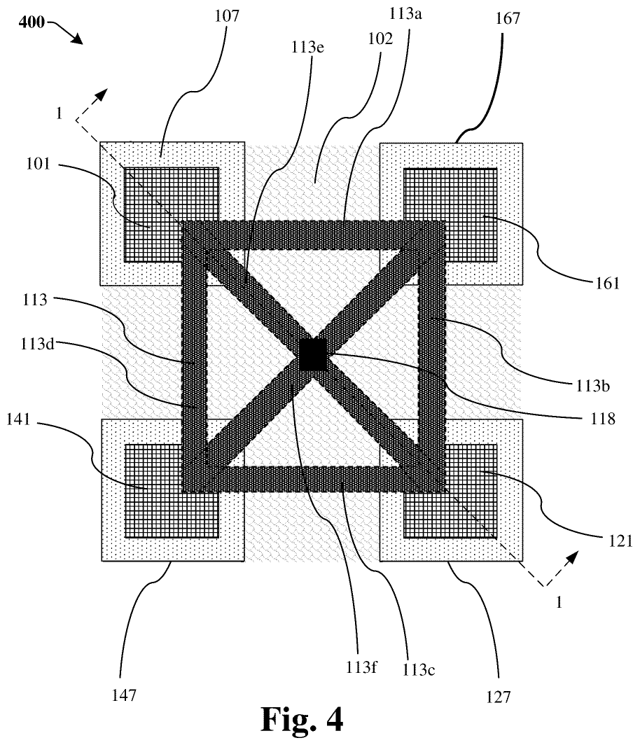

FIG. 4 is a cross-sectional plan view diagram illustrating some embodiments of a portion 400 of a pixel circuit array of an image sensor showing a conductive layer connecting a plurality of floating diffusions to a common contact.

FIG. 4 shows features illustrated and described with respect to FIG. 2 and shows contact 118 connected to conductive layer 113. Conductive layer 113 is shown as comprising one or more of conductive layer features (e.g., strips) 113a, 113b, 113c, 113d, 113e, and 113f. Conductive layer feature 113a lies between and connects floating diffusion region 101 to floating diffusion region 161. Conductive layer feature 113b lies between and connects floating diffusion region 161 to floating diffusion region 121. Conductive layer feature 113c lies between and connects floating diffusion region 121 to floating diffusion region 141. Conductive layer feature 113d lies between and connects floating diffusion region 141 to floating diffusion region 101. Conductive layer feature 113e lies between and connects floating diffusion region 101 to floating diffusion region 121. Conductive layer feature lies between and connects floating diffusion region 141 to floating diffusion region 161.

Contact 118 is shown as being connected to conductive layer 113 at the intersection of conductive layer feature 113e and conductive layer feature 113f. However, contact 118 may be connected anywhere along conductive layer 113, such as at the intersection of conductive layer feature 113a with conductive layer feature 113d, at the intersection of conductive layer feature 113a and conductive layer feature 113b, at the intersection of conductive layer feature 113b and conductive layer feature 113c, at the intersection of conductive layer feature 113c and conductive layer feature 113d, at a location along conductive layer feature 113a, at a location along conductive layer feature 113b, at a location along conductive layer feature 113c, at a location along conductive layer feature 113d, at a location along conductive layer feature 113e, at a location along conductive layer feature 113f, or at a location along another conductive layer feature, such as a conductive layer feature of a different size, shape, or position (e.g., anywhere on a polygonal conductive layer feature).

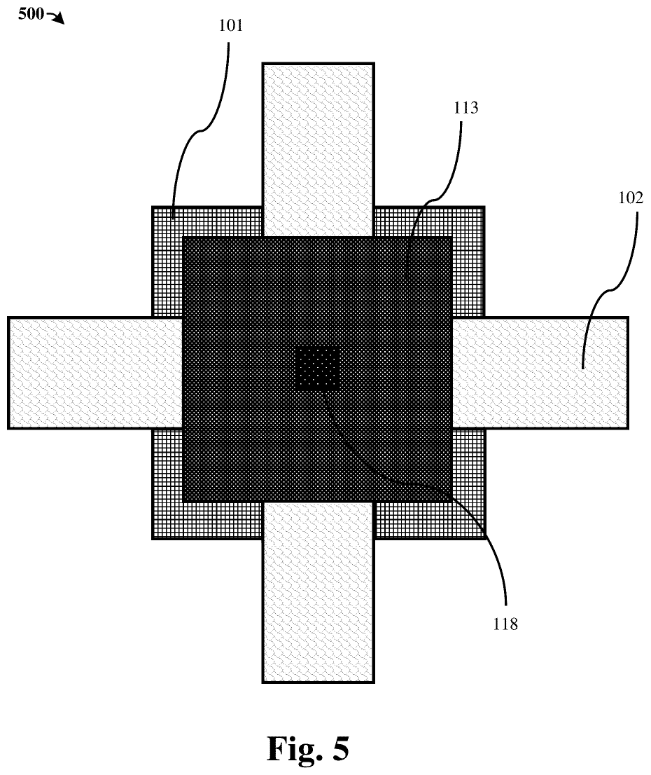

FIG. 5 is a top view diagram illustrating some embodiments of a portion 500 of a pixel circuit array of an image sensor showing a conductive layer connecting a plurality of floating diffusions to a common contact. In the example of FIG. 5, conductive layer 113 is implemented in the form of a polygon (e.g., a rectangle, such as a square) electrically connecting a plurality (e.g., four) floating diffusion regions (e.g., floating diffusion region 101) separated by isolation region 102. In the example of FIG. 5, contact 118 is formed over and connected to conductive layer 113 (e.g., in the center of the polygon). Alternatively, contact 118 could be formed over and connected to any portion of the polygon of conductive layer 113.

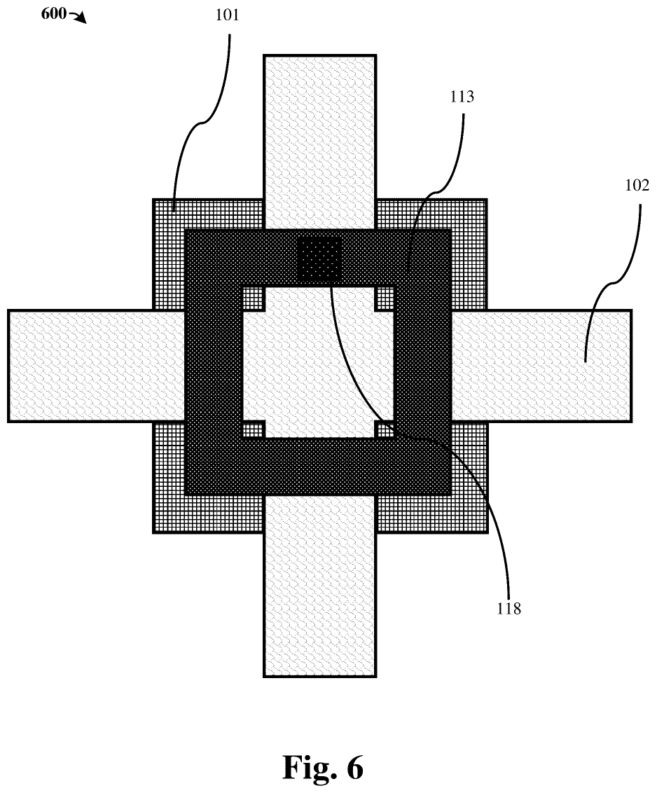

FIG. 6 is a top view diagram illustrating some embodiments of a portion 600 of a pixel circuit array of an image sensor showing a conductive layer connecting a plurality of floating diffusions to a common contact. In the example of FIG. 6, conductive layer 113 is implemented in the form of a ring (e.g., a rectangular frame, such as a square frame) electrically connecting a plurality (e.g., four) floating diffusion regions (e.g., floating diffusion region 101) separated by isolation region 102. In the example of FIG. 6, contact 118 is formed over and connected to a strip forming a side of the ring. Alternatively, contact 118 could be formed over and connected to any portion of the ring of conductive layer 113.

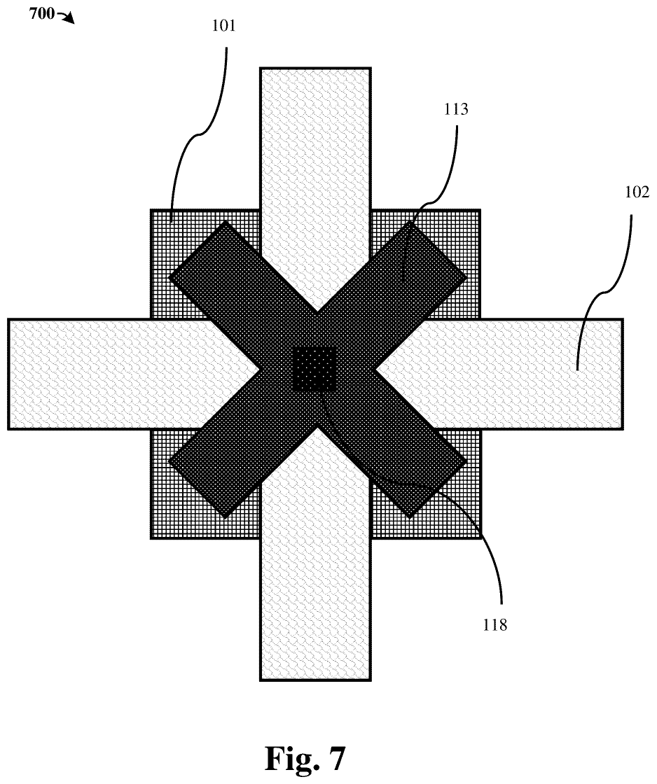

FIG. 7 is a top view diagram illustrating some embodiments of a portion 700 of a pixel circuit array of an image sensor showing a conductive layer connecting a plurality of floating diffusions to a contact. In the example of FIG. 7, conductive layer 113 is implemented in the form of radial strips (e.g., a cross) electrically connecting a plurality (e.g., four) floating diffusion regions (e.g., floating diffusion region 101) separated by isolation region 102. In the example of FIG. 7, contact 118 is formed over and connected to an intersection of the radial strips (e.g., at the center of the radial strip pattern). Alternatively, contact 118 could be formed over and connected to any portion of the radial strip pattern.

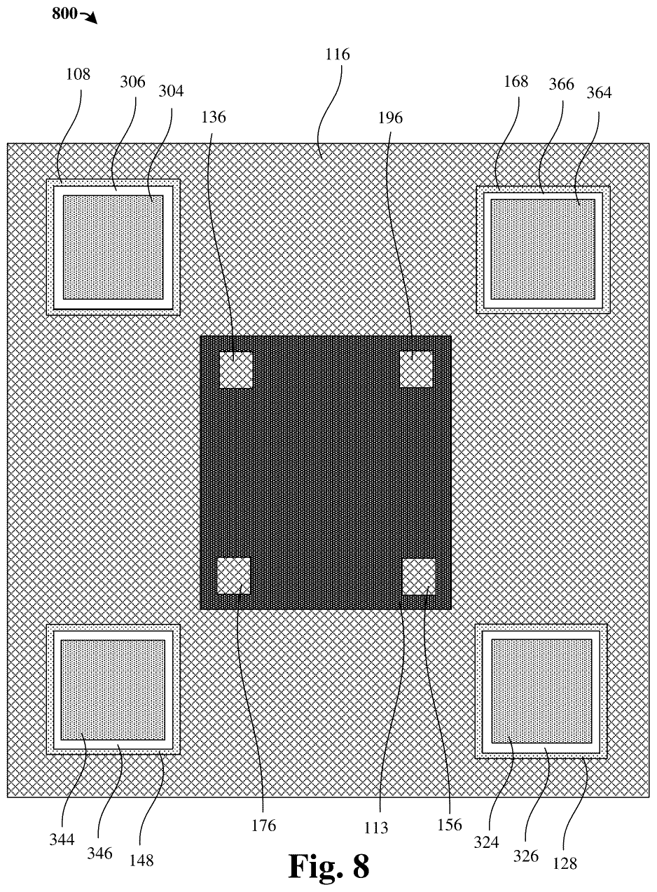

While FIG. 6, FIG. 7, and FIG. 8 show examples of forms (e.g., square, square frame, or cross) of conductive layer 113, a metal connection pattern can be implemented in a variety of shapes, including shapes different from the illustrated examples. For example, a Z or N pattern could be implemented using a diagonal conductor as seen in FIG. 7 together with side elements of a ring (e.g., square frame) as shown in FIG. 6. Any shape, shapes, or pattern that provides electrical connectivity for a common contact to a plurality of floating diffusion regions can be used.

FIG. 8 is a cross-sectional plan view diagram illustrating some embodiments of a portion 800 of a pixel circuit array of an image sensor. A dashed line in FIG. 3 shows the plane of the cross section of FIG. 8. Transistor gate 304 is surrounded by sidewall spacer 306, which is surrounded by a portion of dielectric layer 108. Transistor gate 324 is surrounded by sidewall spacer 326, which is surrounded by a portion of dielectric layer 108 identified as dielectric layer portion 128. Transistor gate 344 is surrounded by sidewall spacer 346, which is surrounded by a portion of dielectric layer 108 identified as dielectric layer portion 148. Transistor gate 364 is surrounded by sidewall spacer 366, which is surrounded by a portion of dielectric layer 108 identified as dielectric layer portion 168. The dielectric layer portions are surrounded by contact etch stop layer 116. Conductive layer 113 is centrally located between the four transistors and is surrounded by contact etch stop layer 116. Depressed areas of conductive layer 113 in contact with underlying floating diffusion regions 101, 121, 141, and 161 are below the plane of FIG. 8, leaving apertures 136, 156, 176, and 196 in conductive layer 113 filled with portions of contact etch stop layer 116.

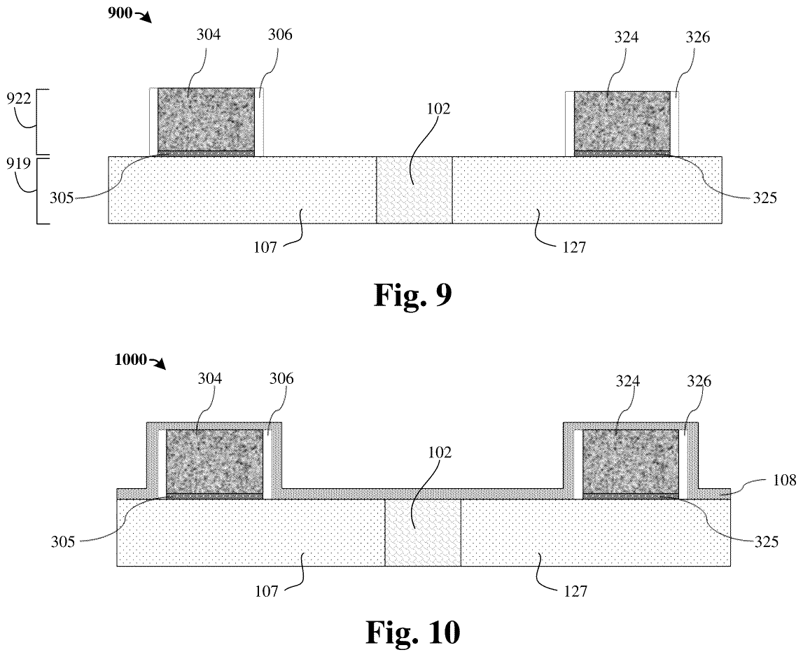

FIGS. 9 through 25 are cross-sectional elevation view diagrams illustrating some embodiments of a series of incremental manufacturing steps as a series of cross-sectional views. Although FIGS. 9 through 25 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 9 is a cross-sectional plan view diagram illustrating some embodiments of a portion 900 of a pixel circuit array of an image sensor. Semiconductor substrate 919 comprises semiconductor substrate region 107, semiconductor substrate region 127, and isolation region 102. Isolation region 102 is formed in a semiconductor substrate, isolating semiconductor substrate region 107 (e.g., p-type semiconductor substrate region) from semiconductor substrate region 127 (e.g., p-type semiconductor substrate region). Gate structure 922 comprises transistor gate dielectric layer 305 and transistor gate 324. Transistor gate dielectric layer 305 is formed on semiconductor substrate region 107. Transistor gate dielectric layer 325 is formed on semiconductor substrate region 127. Transistor gate 304 is formed (e.g., of polysilicon) on transistor gate dielectric layer 305. Transistor gate 324 is formed (e.g., of polysilicon) on transistor gate dielectric layer 325. In some embodiments, transistor gate dielectric layer 305 and transistor gate 304 may be formed by deposition processes followed by patterning processes

Sidewall spacer 306 is formed around transistor gate 304. Sidewall spacer 326 is formed around transistor gate 324. In some embodiments, the sidewall spacer 306 and sidewall spacer 326 may be formed by depositing a sidewall spacer material to continuously extend over transistor gate 304 and transistor gate 324. The sidewall spacer material is subsequently etched to remove the sidewall spacer material from horizontal surfaces, leaving sidewall spacer 306 and sidewall spacer 326 along opposing sides of transistor gate 304 and transistor gate 324. In various embodiments, the sidewall spacer material may comprise silicon nitride, a silicon dioxide (SiO₂), silicon oxy-nitride (e.g., SiON), silicon carbide, Si₃N₄, and/or the like. In various embodiments, the sidewall spacer material may be formed to a thickness of about 500 Angstroms.

FIG. 10 is a cross-sectional plan view diagram illustrating some embodiments of a portion 1000 of a pixel circuit array of an image sensor. A dielectric layer 108 (e.g., dielectric film) is formed over the features described with respect to FIG. 9. As an example, the dielectric layer 108 may be an oxide layer (e.g., silicon dioxide (SiO₂)), a nitride layer (e.g., silicon nitride (SiN)), or the like. In some embodiments, the dielectric layer 108 may be formed using a deposition process (e.g., a physical vapor deposition (PVD) process, a chemical vapor deposition (CVD) process, a plasma enhanced CVD (PE-CVD) process, a low-pressure chemical vapor deposition (LPCVD) process, an ion beam deposition, sputtering, or the like).

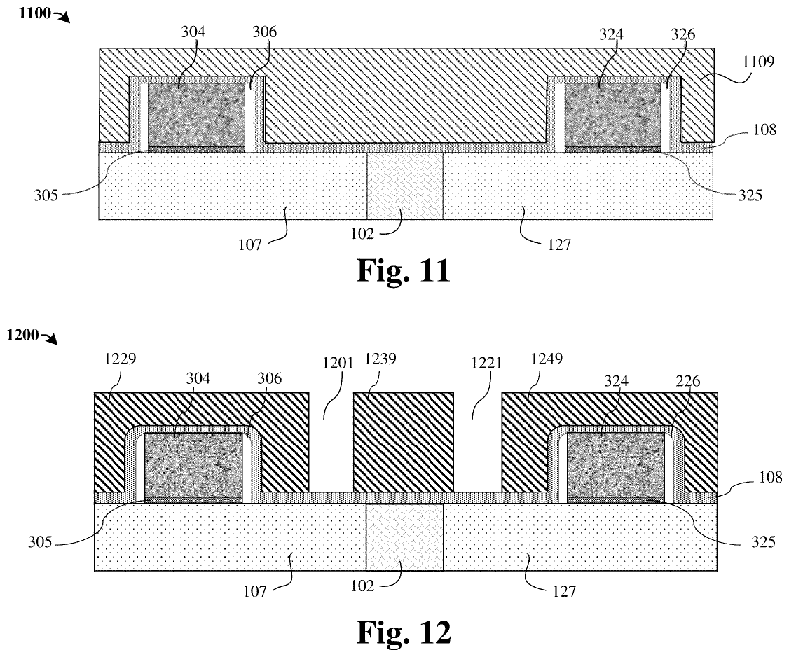

FIG. 11 is a cross-sectional plan view diagram illustrating some embodiments of a portion 1100 of a pixel circuit array of an image sensor. A first patterning layer 1109 (e.g., a photoresist layer, a hard mask layer, or the like) is applied to the structure illustrated in FIG. 10, resulting in the structure shown in FIG. 11. In some embodiments, a photolithographic technique can be used to expose the first patterning layer 1109 to electromagnetic energy (e.g., light) in a pattern that distinguishes regions from which the first patterning layer 1109 is to be removed from regions where the first patterning layer 1109 is to remain.

FIG. 12 is a cross-sectional plan view diagram illustrating some embodiments of a portion 1200 of a pixel circuit array of an image sensor. After patterned photolithographic exposure, a removal technique (e.g., comprising a chemical photoresist developer) is performed on first patterning layer (e.g., 1109 if FIG. 9) to yield openings 1201 and 1221 where the first patterning layer has been removed to expose portions of dielectric layer 108. First patterning layer regions 1229, 1239, and 1249 of first patterning layer remain.

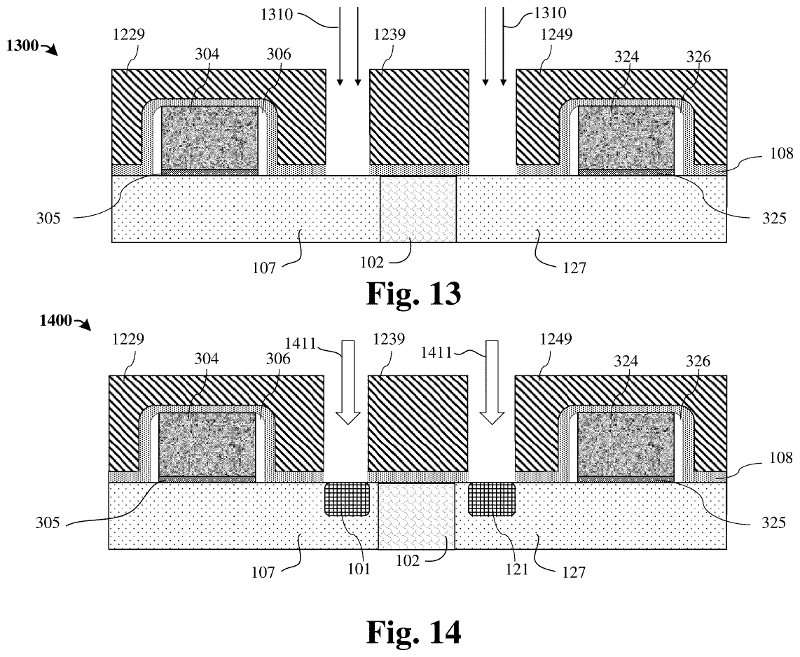

FIG. 13 is a cross-sectional plan view diagram illustrating some embodiments of a portion 1300 of a pixel circuit array of an image sensor. Etchant 1310 is applied to yield openings in dielectric layer 108 aligned with the openings (e.g., 1201 and 1221 of FIG. 12) through first patterning layer, exposing semiconductor substrate regions 107 and 127 through respective openings. The etching technique may, for example, be a dry etching technique suitable for etching through dielectric layer 108. In various embodiments, the etchant 1310 may comprise a plasma etch with tetrafluoromethane (CF₄), sulfur hexafluoride (SF₆), nitrogen trifluoride (NF₃), or the like.

FIG. 14 is a cross-sectional plan view diagram illustrating some embodiments of a portion 1400 of a pixel circuit array of an image sensor. An implantation technique can be performed to form floating diffusion region 101 and floating diffusion region 121 through respective openings formed as described with respect to FIG. 12 and FIG. 13. FIG. 14 shows ions 1411 used for the implantation technique. In some embodiments, the ions 1411 may comprise a dopant species such as phosphorus, arsenic, antimony, or the like.

FIG. 15 is a cross-sectional plan view diagram illustrating some embodiments of a portion 1500 of a pixel circuit array of an image sensor. Remaining portions of first patterning layer (e.g., 1109 if FIG. 9), including first patterning layer regions (e.g., 1229, 1239, and 1249 of FIG. 12), are removed using a cleaning technique (e.g., a plasma washing process), leaving dielectric layer 108 with floating diffusion regions 101 and 121 underlying their respective openings in dielectric layer 108.

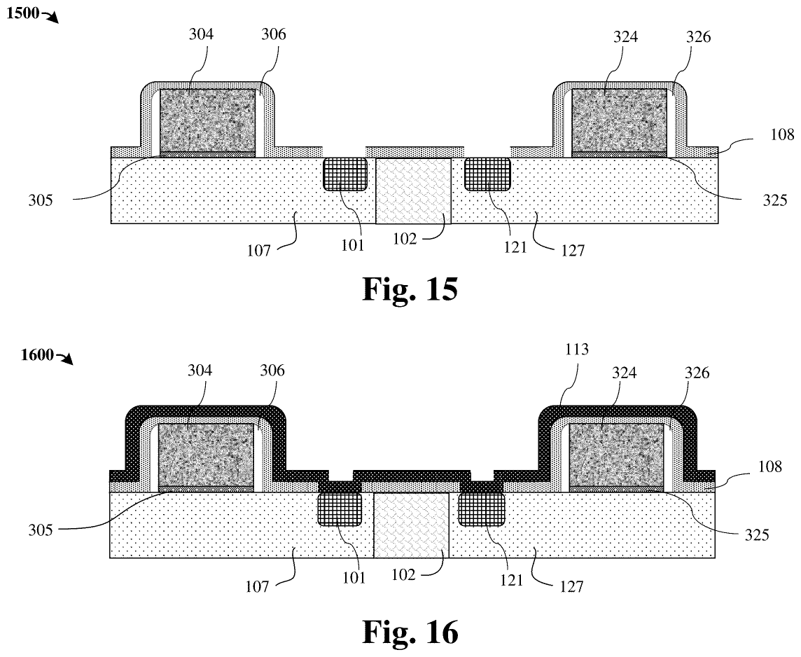

FIG. 16 is a cross-sectional plan view diagram illustrating some embodiments of a portion 1600 of a pixel circuit array of an image sensor. A conductive layer 113 (e.g., a metal film, such as titanium nitride (TiN)) is deposited over dielectric layer 108 and over and in contact with floating diffusion regions 101 and 121 through their respective openings in dielectric layer 108. In some embodiments, the conductive layer 113 may comprise a metal that is formed by for example, CVD, PVD, ALD, sputtering, electrochemical plating, electroless plating, some other deposition process, or a combination of the foregoing.

In some embodiments, conductive layer 113 may be a conductive material, such as a metal or a metal compound, for example, titanium nitride, tantalum nitride, titanium, tantalum, copper, aluminum, or a combination of one or more of the foregoing. Further, conductive layer 113 may be, for example, about 10-100 nanometers thick in some embodiments. Conductive layer 113 may be formed to have a height above semiconductor substrate region 107 and above semiconductor substrate region 127 less than a gate height of transistor gate 304 and transistor gate 324 above semiconductor substrate region 107 and above semiconductor substrate region 127.

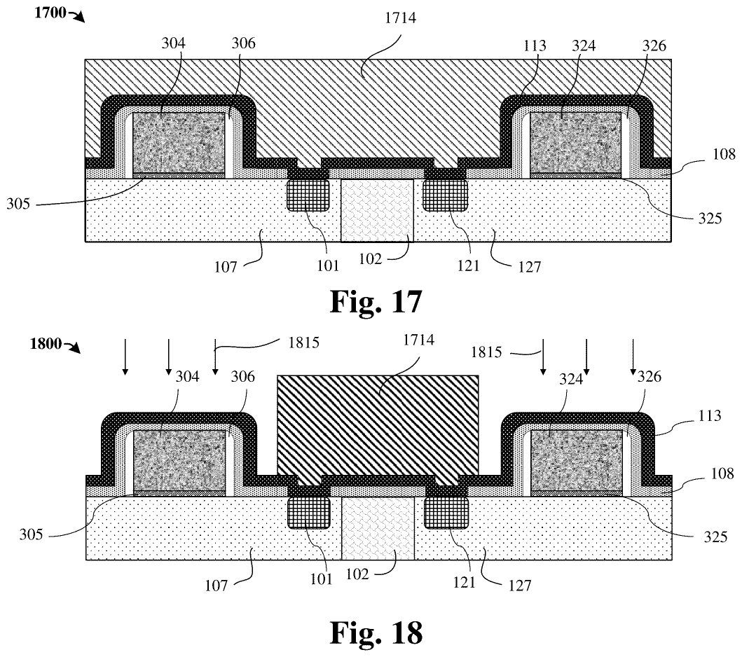

FIG. 17 is a cross-sectional plan view diagram illustrating some embodiments of a portion 1700 of a pixel circuit array of an image sensor. A second patterning layer 1714 (e.g., a photoresist layer, a hard mask layer, or the like) is applied to conductive layer 113 of the structure illustrated in FIG. 16, resulting in the structure shown in FIG. 17. In some embodiments, a photolithographic technique can be used to expose the second patterning layer 1714 to electromagnetic energy (e.g., light) in a pattern that distinguishes regions from which the second patterning layer 1714 is to be removed from regions where the second patterning layer 1714 is to remain.

FIG. 18 is a cross-sectional plan view diagram illustrating some embodiments of a portion 1800 of a pixel circuit array of an image sensor. A removal technique (e.g., a photoresist developer) is applied to second patterning layer 1714, removing portions of second patterning layer 1714 over transistor gate 304 and transistor gate 324 but leaving a portion of second patterning layer 1714 over regions where conductive layer 113 is to remain, including over floating diffusion region 101 and floating diffusion region 121 and a region electrically connecting floating diffusion region 101 to floating diffusion region 121. Etchant 1815 is applied to remove portions of conductive layer 113 beyond the portion of conductive layer 113 that is to remain to electrically connect a plurality of floating diffusion regions together. The etching technique may, for example, be a dry etching technique suitable for etching through exposed regions of conductive layer 113.

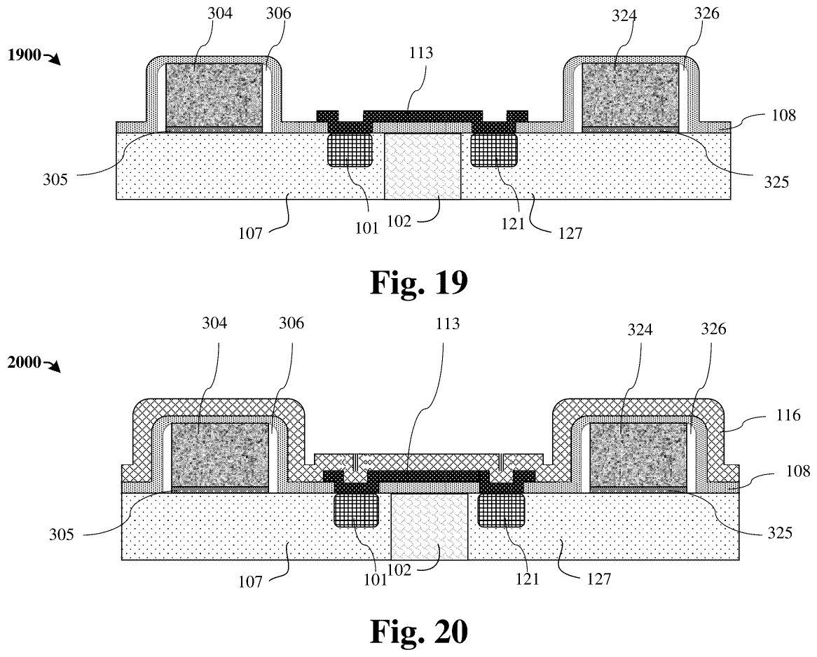

FIG. 19 is a cross-sectional plan view diagram illustrating some embodiments of a portion 1900 of a pixel circuit array of an image sensor. Any remaining portion of second patterning layer (e.g., 1714 of FIG. 18) is removed using a cleaning technique, leaving the portion of conductive layer 113 which electrically connects floating diffusion region 101 to floating diffusion region 121.

FIG. 20 is a cross-sectional plan view diagram illustrating some embodiments of a portion 2000 of a pixel circuit array of an image sensor. A contact etch stop layer 116, for example, silicon nitride (SiN), is formed over the remaining portion of conductive layer 113 and the remaining portions of dielectric layer 108. In some embodiments, the contact etch stop layer 116 may be formed using a deposition process (e.g., a PVD process, a CVD process, a PE-CVD process, a LPCVD process, an ion beam deposition, sputtering, or the like).

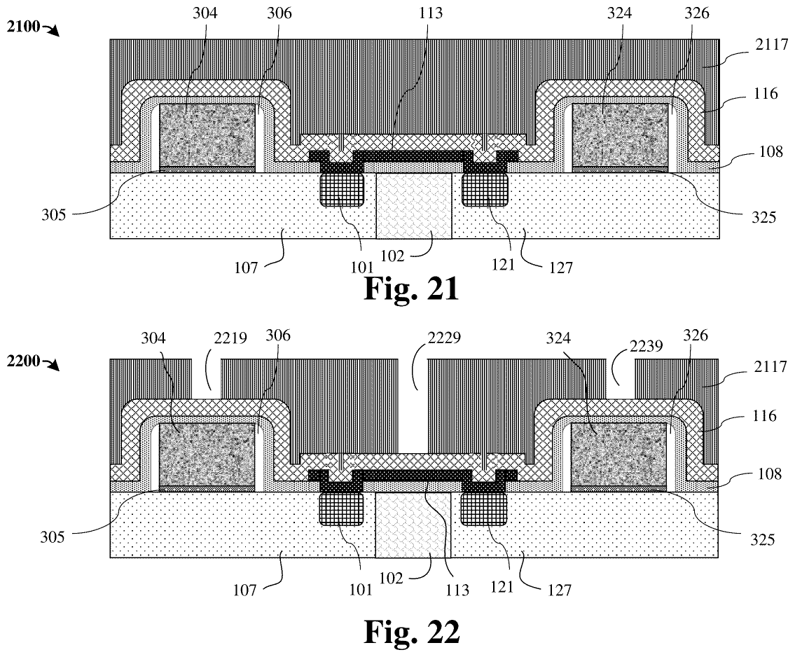

FIG. 21 is a cross-sectional plan view diagram illustrating some embodiments of a portion 2100 of a pixel circuit array of an image sensor. An interlayer dielectric 2117 is formed over contact etch stop layer 116. In some embodiments, the interlayer dielectric 2117 may comprise one or more of silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), or the like.

FIG. 22 is a cross-sectional plan view diagram illustrating some embodiments of a portion 2200 of a pixel circuit array of an image sensor. Openings 2219, 2229, and 2239 are formed in interlayer dielectric 2117, exposing respective portions of contact etch stop layer 116. In some embodiments, openings 2219, 2229, and 2239 may be formed by a first etching process.

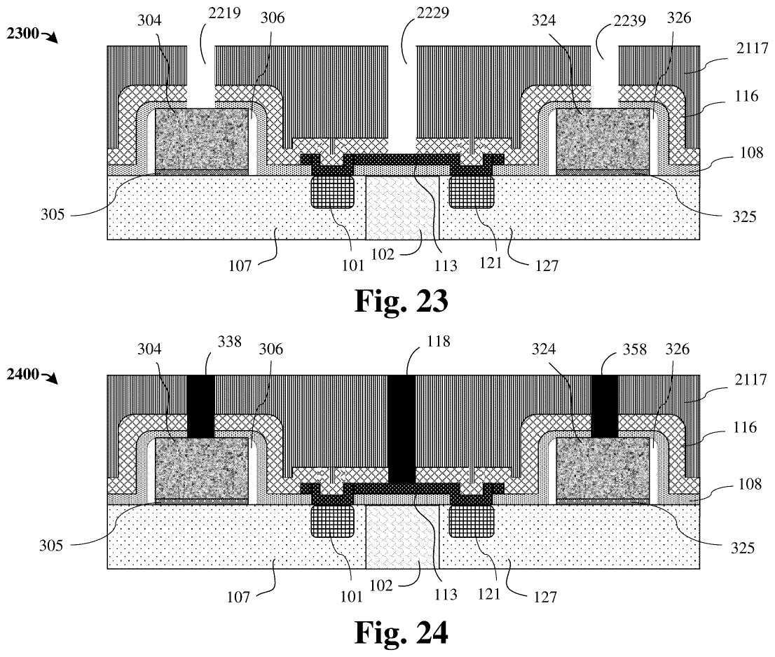

FIG. 23 is a cross-sectional plan view diagram illustrating some embodiments of a portion 2300 of a pixel circuit array of an image sensor. Openings 2219, 2229, and 2239 are extended through contact etch stop layer 116 and, for openings 2219 and 2239, through dielectric layer 108, exposing a portion of a first surface of transistor gate 304 through opening 2219, a portion of a first surface of transistor gate 324 through opening 2239, and a portion of conductive layer 113 through opening 2229. In some embodiments, openings 2219, 2229, and 2239 may be extended through contact etch stop layer 116 by the first etching process. In other embodiments, openings 2219, 2229, and 2239 may be extended through contact etch stop layer 116 by a second etching process that is separate from the first etching process.

FIG. 24 is a cross-sectional plan view diagram illustrating some embodiments of a portion 2400 of a pixel circuit array of an image sensor. Contacts 338, 118, and 358 are formed of an electrically conductive material (e.g., metal) through openings (e.g., 2219, 2229, and 2239 of FIG. 23), respectively. In some embodiments, the contacts 338, 118, and 358 may by formed by depositing a metal within openings (e.g., 2219, 2229, and 2239 of FIG. 23), followed by a planarization process (e.g., a chemical mechanical planarization process). In some embodiments, the metal may be formed by for example, CVD, PVD, ALD, sputtering, electrochemical plating, electroless plating, some other deposition process, or a combination of the foregoing.

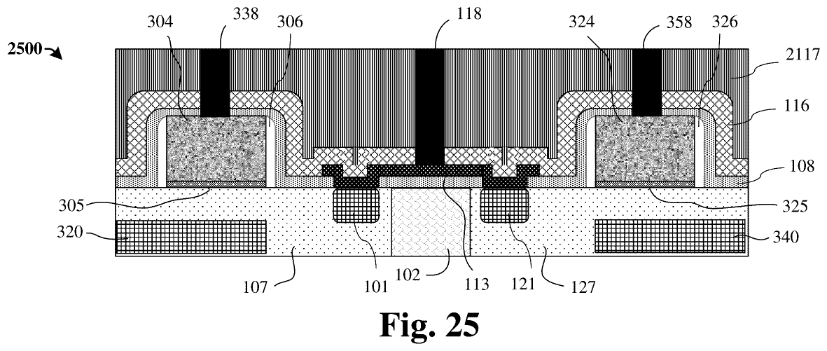

FIG. 25 is a cross-sectional plan view diagram illustrating some embodiments of a portion 2500 of a pixel circuit array of an image sensor. FIG. 25 differs from FIG. 24 in that it includes semiconductor region 320 and semiconductor region 340 formed within respective regions of the semiconductor substrate, resulting in p-type/n-type (PN) junctions to form photodiodes sensitive to electromagnetic energy (e.g., light). By detecting light incident upon photodiodes, the image sensor can assign intensity levels to pixels among an array of pixels of the image sensor. While the semiconductor regions 320 and 340 are illustrated following other fabrication techniques, formation of the semiconductor regions can be performed earlier, and the sizes, shapes, and locations of the semiconductor regions can be different from the example illustrated in FIG. 25. After processing is completed, for example after features such as those shown in FIG. 25 are formed, such a wafer can optionally be stacked with other wafers or die and then singulated into individual dies which correspond to individual integrated circuit structures

While not explicitly illustrated, it is understood that a source region and a drain region may be disposed within the semiconductor substrate (e.g., semiconductor substrate region 107 or semiconductor substrate region 127) to form, with transistor gate 304 or transistor gate 324, a transistor, which may be used, for example, as a transfer transistor or a reset transistor for a pixel circuit of the image sensor. The source and drain regions can, for example, be doped to have a first conductivity type which is opposite a second conductivity type of a channel region under the transistor gate dielectric layers 305 and 325. Transistor gates 304 and 324 may be, for example, doped polysilicon or a metal, such as aluminum, copper, or combinations thereof. Transistor gate dielectric layers 305 and 325 may be, for example, an oxide, such as silicon dioxide, or a dielectric material of a high dielectric constant. Sidewall spacers 306 and 326 may be, for example, made of silicon nitride (e.g., Si₃N₄). Contacts 118, 338, and 358 may be, for example, made of a metal, such as copper or tungsten.

As can be seen, illustrated integrated circuit features can have a square, rectangular, or circular shape when viewed from above in some embodiments. In other embodiments, however, for example due to practicalities of many etch processes, the corners of the illustrated square shape can become rounded, resulting in features having a square or rectangular shape with rounded corners, or having a circular or oval shape.

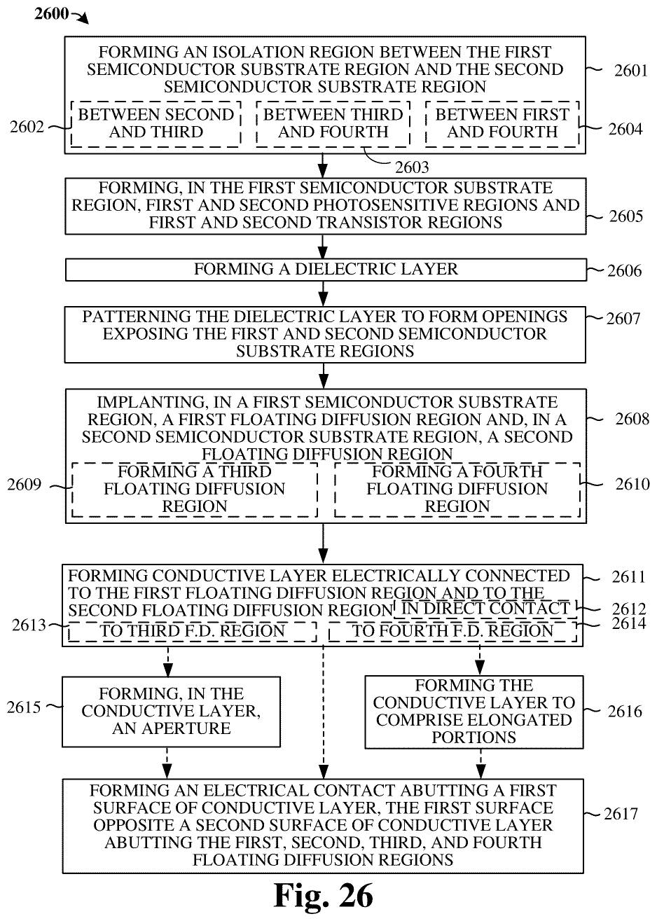

FIG. 26 is a flow diagram illustrating a methodology 2600 in flowchart format in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At block 2601, an isolation region is formed between the first semiconductor substrate region and the second semiconductor substrate region. In some embodiments, the FIG. 9 illustrates a cross-sectional view corresponding to block 2601. Block 2601 may further comprise one or more of blocks 2602, 2603, and 2604. At block 2602, an isolation region is formed between the second semiconductor substrate region and a third semiconductor substrate region. At block 2603, an isolation region is formed between the third semiconductor substrate region and a fourth semiconductor substrate region. At block 2604, an isolation region is formed between the first semiconductor substrate region and the fourth semiconductor substrate region.

At block 2605, first and second photosensitive regions and first and second transistor regions are formed in a first semiconductor substrate. In some embodiments, the FIGS. 9-14 illustrate cross-sectional views corresponding to block 2605.

At block 2606, a dielectric layer is formed. The dielectric layer extends from over the isolation region to over the first semiconductor substrate region and to over the second semiconductor substrate region.

At block 2607, the dielectric layer is patterned to form openings exposing the first semiconductor substrate region and the second semiconductor substrate region. The openings formed are co-extensive with the surfaces of a first floating diffusion region to be formed in the first semiconductor substrate region and a second floating diffusion region to be formed in the second semiconductor substrate region.

At block 2608, a first floating diffusion region is formed in a first semiconductor substrate region, and a second floating diffusion region is formed in a second semiconductor substrate region. Block 2608 may further comprise either or both of blocks 2609 and 2610. At block 2609, a third floating diffusion region is formed in a third semiconductor substrate region. At block 2610, a fourth floating diffusion region is formed in a fourth semiconductor substrate region. The floating diffusion regions may be formed, for example, by implanting or the like.

At block 2611, a conductive layer electrically connected to the first floating diffusion region and to the second floating diffusion region is formed over the first floating diffusion region and the second floating diffusion region. In some embodiments, the FIGS. 16-19 illustrate cross-sectional views corresponding to block 2611. Block 2611 may further comprise one or more of blocks 2612, 2613, and 2614. At block 2612, the conductive layer is formed in direct contact with the first floating diffusion region and the second floating diffusion region. At block 2613, the conductive layer is formed to extend to and electrically connect to a third floating diffusion region, with which it may make direct contact. At block 2614, the conductive layer is formed to extend to and electrically connect to a fourth floating diffusion region, with which it may make direct contact. At block 2615, an aperture may be formed in the conductive layer in some embodiments.

At block 2616, the conductive layer may be formed to comprise elongated portions in some embodiments. For example, the conductive layer may be formed to comprise radially oriented elongated portions extending outward from a central area to connect with a plurality of the first, second, third, and fourth floating diffusion regions. Any or all of blocks 2611, 2612, 2613, 2614, 2615, and 2616 may be performed separately or combined to be performed together, for example, simultaneously. For example, selectivity of formation of the conductive layer may be provided using deposition or etching techniques, allowing additive or subtractive manufacturing techniques to accomplish patterned conductive layer formation.

At block 2617, an electrical contact abutting and electrically connected to a first surface of the conductive layer is formed, where the first surface is opposite a second surface of the conductive layer abutting and electrically connected to a plurality of the first, second, third, and fourth floating diffusion regions. In some embodiments, the FIGS. 22-24 illustrate cross-sectional views corresponding to block 2617.

Some embodiments relate to an integrated circuit including a plurality of floating diffusion regions ohmically connected to a common contact via a patterned conductive layer, obviating a need for individual contacts for each floating diffusion region. The integrated circuit includes a semiconductor substrate and an interconnect structure disposed over the semiconductor substrate. The interconnect structure includes a plurality of dielectric layers and a conductive layer that are stacked over one another in alternating fashion. A contact electrode is disposed over and in direct and ohmic contact with the conductive layer. The conductive layer is directly connected to a respective surface of each of a plurality of floating diffusion regions. In some embodiments, the conductive layer is ohmically (e.g., directly and ohmically) connected to a respective surface of each of a plurality of floating diffusion regions. The respective surfaces connected by the conductive layer are co-planar with one another. Each floating diffusion region can be associated with a respective pixel of an array of pixels of an image sensor. As used herein, the words “ohmic” and “ohmically” refer to a direct physical contact electrical connection at a surface interface between two electrically conductive or semiconductive components.

Some embodiments relate to an integrated circuit, wherein the integrate circuit includes a first floating diffusion region situated within a first semiconductor substrate region. The integrated circuit also includes a second floating diffusion region situated within a second semiconductor substrate region. The integrated circuit further includes an isolation region disposed between the first semiconductor substrate region and the second semiconductor substrate region. The integrated circuit also includes a gate structure disposed over the substrate abutting the first semiconductor substrate region. The integrated circuit further includes a conductive layer directly (e.g., directly and ohmically) connected to the first floating diffusion region and to the second floating diffusion region. The gate structure has a greater maximum height than the conductive layer.

In some embodiments, the integrated circuit further includes a third floating diffusion region situated within a third semiconductor substrate region. The isolation region is disposed between the third floating diffusion region and the first floating diffusion region and between the third floating diffusion region and the second floating diffusion region. The conductive layer is electrically connected to the third floating diffusion region. The integrated circuit further includes a fourth floating diffusion region situated within a fourth semiconductor substrate region. The isolation region is disposed between the fourth floating diffusion region and the first floating diffusion region, between the fourth floating diffusion region and the second floating diffusion region, and between the fourth floating diffusion region and the third floating diffusion region. The conductive layer is electrically connected to the fourth floating diffusion region.

In some embodiments, the integrated circuit further includes a first interlayer dielectric (ILD) layer surrounding a first conductive contact physically contacting the gate structure and further surrounding a second conductive contact physically contacting a top of the conductive layer.

In some embodiments, the integrated circuit further includes an electrical contact abutting a first surface of the conductive layer, the first surface opposite a second surface of the conductive layer abutting the first floating diffusion region and the second floating diffusion region.

In some embodiments, the conductive layer has sidewalls that form an aperture overlying a portion of the isolation region. The aperture is located between each of two diagonally opposite pairs selected among the first semiconductor substrate region, the second semiconductor substrate region, the third semiconductor substrate region, and the fourth semiconductor substrate region.

In some embodiments, the conductive layer comprises a first elongated portion extending from a central region to a first connection region adjoining the first floating diffusion region. The conductive layer also comprises a second elongated portion extending from the central region to a second connection region adjoining the second floating diffusion region. The conductive layer also comprises a third elongated portion extending from the central region to a third connection region adjoining the third floating diffusion region. The conductive layer also comprises a fourth elongated portion extending from the central region to a fourth connection region adjoining the fourth floating diffusion region.

In some embodiments, a first sensor structure comprises a first transistor region, a first photosensitive region, and the first floating diffusion region. The first photosensitive region is situated in the first semiconductor substrate region. The first transistor region is situated in the first semiconductor substrate region between the first photosensitive region and the first floating diffusion region. A second sensor structure comprises a second transistor region, a second photosensitive region, and the second floating diffusion region. The second photosensitive region is situated in the second semiconductor substrate region. The second transistor region is situated in the second semiconductor substrate region between the second photosensitive region and the second floating diffusion region.

Some embodiments relate to a pixel element array including an isolation region. The pixel element array also includes a plurality of pixel elements adjoining the isolation region along different isolation region surfaces. Each of the plurality of pixel elements includes a respective floating diffusion region. A dielectric layer extends over the isolation region and has sidewalls forming openings over the respective floating diffusion region within the plurality of pixel elements. A conductive layer extends from over the dielectric layer to adjoin in direct and ohmic connection a respective first floating diffusion region surface of each respective floating diffusion region of each of the plurality of pixel elements. A contact etch stop layer disposed over and along sidewalls of the conductive layer.

In some embodiments, the pixel element array also includes an electrical contact extending through the contact etch stop layer and abutting a first conductive layer surface of the conductive layer opposite a second conductive layer surface adjoining each respective first floating diffusion region surface. The electrical contact is in direct and ohmic contact with the first conductive layer surface. The electrical contact provides a common electrical connection for the plurality of pixel elements with each respective floating diffusion region electrically connected to the electrical contact via the conductive layer.

In some embodiments, the pixel element array also includes a transfer gate arranged over the pixel elements. The dielectric layer and the contact etch stop layer continuously extend from below a top of the transfer gate to above the top of the transfer gate.

In some embodiments, the conductive layer comprises a plurality of elongated portions extending radially outward from a center of the conductive layer to provide the direct and ohmic connection to each respective first floating diffusion region surface.

In some embodiments, an interior boundary of the conductive layer is formed by sidewalls of the conductive layer that extend in a closed loop around the contact etch stop layer.

In some embodiments, a respective portion of the conductive layer adjoining the respective floating diffusion region is surrounded by the dielectric layer. A common portion of the conductive layer adjoining the dielectric layer distal to the respective floating diffusion region.

Some embodiments relate to a method for manufacturing an integrated circuit. The method includes forming an isolation region between a first semiconductor substrate region and a second semiconductor substrate region. The method also includes forming a dielectric layer extending from over the isolation region to over the first substrate region and the second substrate region. The method further includes patterning the dielectric layer to form openings exposing the first semiconductor substrate region and the second semiconductor substrate region. The method also includes implanting the substrate according to the openings to form a first floating diffusion region in the first semiconductor substrate region and a second floating diffusion region in the second semiconductor substrate region. The method further includes forming a conductive layer over the dielectric layer and within the openings, the conductive layer being electrically connected to the first floating diffusion region and to the second floating diffusion region.

In some embodiments, the forming, in the first semiconductor substrate region, the first floating diffusion region and, in the second semiconductor substrate region, the second floating diffusion region further comprises forming, in a third semiconductor substrate region, a third floating diffusion region and, in a fourth semiconductor substrate region, a fourth floating diffusion region. The forming the isolation region between the first semiconductor substrate region and the second semiconductor substrate region further comprises forming the isolation region to further be situated between the second semiconductor substrate region and the third semiconductor substrate region, between the third semiconductor substrate region and the fourth semiconductor substrate region, and between the fourth semiconductor substrate region and the first semiconductor substrate region. The forming the conductive layer electrically connected to the first floating diffusion region and to the second floating diffusion region further comprises forming the conductive layer electrically connected to the third floating diffusion region and to the fourth floating diffusion region.

In some embodiments, the method further comprises forming an electrical contact abutting a first surface of the conductive layer. The first surface is opposite a second surface of the conductive layer abutting the first floating diffusion region, the second floating diffusion region, the third floating diffusion region, and the fourth floating diffusion region.

In some embodiments, the method further comprises patterning the conductive layer to form an aperture overlying a portion of the isolation region. The aperture is located between each of two diagonally opposite pairs selected among the first semiconductor substrate region, the second semiconductor substrate region, a third semiconductor substrate region, and a fourth semiconductor substrate region.

In some embodiments, the method further comprises patterning the conductive layer to comprise a first elongated portion extending from a central region to a first connection region adjoining the first floating diffusion region, a second elongated portion extending from the central region to a second connection region adjoining the second floating diffusion region, a third elongated portion extending from the central region to a third connection region adjoining the third floating diffusion region, and a fourth elongated portion extending from the central region to a fourth connection region adjoining the fourth floating diffusion region.

In some embodiments, the method further comprises forming, in the first semiconductor substrate region, a first photosensitive region and a first transistor region, and, in the second semiconductor substrate region, a second photosensitive region and a second transistor region. The first photosensitive region is situated in the first semiconductor substrate region. The first transistor region is situated in the first semiconductor substrate region between the first photosensitive region and the first floating diffusion region. A second sensor structure comprises the second transistor region, the second photosensitive region, and the second floating diffusion region. The second photosensitive region is situated in the second semiconductor substrate region. The second transistor region is situated in the second semiconductor substrate region between the second photosensitive region and the second floating diffusion region.

In some embodiments, the forming the conductive layer further comprises forming the conductive layer in direct and ohmic contact with the first floating diffusion region and in direct and ohmic contact with the second floating diffusion region.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a semiconductor substrate comprising a first semiconductor substrate region and a second semiconductor substrate region;
a first floating diffusion region situated within the first semiconductor substrate region;
a second floating diffusion region situated within the second semiconductor substrate region;
an isolation region disposed between the first semiconductor substrate region and the second semiconductor substrate region;
a gate structure disposed over the semiconductor substrate abutting the first semiconductor substrate region; and
a conductive layer directly connected to the first floating diffusion region and to the second floating diffusion region, wherein the gate structure has a greater maximum height than the conductive layer.

2. The integrated circuit of claim 1, further comprising:
a third floating diffusion region situated within a third semiconductor substrate region, wherein the isolation region is disposed between the third floating diffusion region and the first floating diffusion region and between the third floating diffusion region and the second floating diffusion region, and wherein the conductive layer is electrically connected to the third floating diffusion region; and
a fourth floating diffusion region situated within a fourth semiconductor substrate region, wherein the isolation region is disposed between the fourth floating diffusion region and the first floating diffusion region, between the fourth floating diffusion region and the second floating diffusion region, and between the fourth floating diffusion region and the third floating diffusion region, and wherein the conductive layer is electrically connected to the fourth floating diffusion region.

3. The integrated circuit of claim 2, wherein the conductive layer has sidewalls that form an aperture overlying a portion of the isolation region, the aperture located between each of two diagonally opposite pairs selected among the first semiconductor substrate region, the second semiconductor substrate region, the third semiconductor substrate region, and the fourth semiconductor substrate region.

4. The integrated circuit of claim 2, wherein the conductive layer comprises a first elongated portion extending from a central region to a first connection region adjoining the first floating diffusion region, a second elongated portion extending from the central region to a second connection region adjoining the second floating diffusion region, a third elongated portion extending from the central region to a third connection region adjoining the third floating diffusion region, and a fourth elongated portion extending from the central region to a fourth connection region adjoining the fourth floating diffusion region.

5. The integrated circuit of claim 1, further comprising:
a first interlayer dielectric (ILD) layer surrounding a first conductive contact physically contacting the gate structure and further surrounding a second conductive contact physically contacting a top of the conductive layer.

6. The integrated circuit of claim 1, further comprising:
an electrical contact abutting a first surface of the conductive layer, the first surface opposite a second surface of the conductive layer abutting the first floating diffusion region and the second floating diffusion region.

7. The integrated circuit of claim 1,
wherein a first sensor structure comprises a first transistor region, a first photosensitive region, and the first floating diffusion region, wherein the first photosensitive region is situated in the first semiconductor substrate region, the first transistor region is situated in the first semiconductor substrate region between the first photosensitive region and the first floating diffusion region, and
wherein a second sensor structure comprises a second transistor region, a second photosensitive region, and the second floating diffusion region, wherein the second photosensitive region is situated in the second semiconductor substrate region, the second transistor region is situated in the second semiconductor substrate region between the second photosensitive region and the second floating diffusion region.

8. A pixel element array comprising:
an isolation region;
a plurality of pixel elements adjoining the isolation region along different isolation region surfaces, each of the plurality of pixel elements comprising a respective floating diffusion region;
a dielectric layer extending over the isolation region and having sidewalls forming openings over the respective floating diffusion region within the plurality of pixel elements;
a conductive layer extending from over the dielectric layer to adjoin in direct and ohmic connection a respective first floating diffusion region surface of each respective floating diffusion region of each of the plurality of pixel elements; and
a contact etch stop layer disposed over and along sidewalls of the conductive layer.

9. The pixel element array of claim 8 further comprising:
an electrical contact extending through the contact etch stop layer and abutting a first conductive layer surface of the conductive layer opposite a second conductive layer surface adjoining each respective first floating diffusion region surface, the electrical contact in direct and ohmic contact with the first conductive layer surface, the electrical contact providing a common electrical connection for the plurality of pixel elements with each respective floating diffusion region electrically connected to the electrical contact via the conductive layer.

10. The pixel element array of claim 8, further comprising:
a transfer gate arranged over the pixel elements, wherein the dielectric layer and the contact etch stop layer continuously extend from below a top of the transfer gate to above the top of the transfer gate.

11. The pixel element array of claim 8, wherein the conductive layer comprises a plurality of elongated portions extending radially outward from a center of the conductive layer to provide the direct and ohmic connection to each respective first floating diffusion region surface.

12. The pixel element array of claim 8, wherein an interior boundary of the conductive layer is formed by sidewalls of the conductive layer that extend in a closed loop around the contact etch stop layer.

13. The pixel element array of claim 8, wherein a respective portion of the conductive layer adjoining the respective floating diffusion region is surrounded by the dielectric layer, with a common portion of the conductive layer adjoining the dielectric layer distal to the respective floating diffusion region.

14. An integrated circuit, comprising:
a first gate structure and a second gate structure disposed over a substrate;
an isolation region disposed within the substrate laterally between the first gate structure and the second gate structure;
a first floating diffusion region disposed within the substrate laterally between the first gate structure and the isolation region;
a second floating diffusion region disposed within the substrate laterally between the second gate structure and the isolation region;
a conductive layer directly connected to the first floating diffusion region and to the second floating diffusion region; and
a conductive contact contacting the conductive layer along an interface that is below tops of the first gate structure and the second gate structure.

15. The integrated circuit of claim 14, further comprising:
a dielectric arranged over the substrate and laterally between the first floating diffusion region and the second floating diffusion region, wherein the conductive layer extends along sidewalls and an upper surface of the dielectric.

16. The integrated circuit of claim 14, wherein the conductive layer comprises ‘U’ shaped segments disposed over the first floating diffusion region and the second floating diffusion region.

17. The integrated circuit of claim 14, wherein the conductive contact vertically contacts the conductive layer between opposing outermost edges of the isolation region.

18. The integrated circuit of claim 14, further comprising:
a second conductive contact that contacts an upper surface of the first gate structure, wherein the second conductive contact has a smaller height than the conductive contact.

19. The integrated circuit of claim 14, further comprising:
a third floating diffusion region disposed within the substrate and laterally separated from the first floating diffusion region along a first direction, wherein the first floating diffusion region is laterally separated from the second floating diffusion region along a second direction that is perpendicular to the first direction in a top-view;
a fourth floating diffusion region disposed within the substrate, wherein the fourth floating diffusion region is laterally separated from the second floating diffusion region along the first direction and is further laterally separated from the third floating diffusion region along the second direction; and
wherein the conductive layer continuously extends over the first floating diffusion region, the second floating diffusion region, the third floating diffusion region, and the fourth floating diffusion region.

20. The integrated circuit of claim 14, further comprising:
a contact etch stop layer disposed along an upper surface and sidewalls of the conductive layer and along upper surfaces and sidewalls of the first gate structure and the second gate structure.
